(19) United States
(12) Patent Application Publication
(10) Pub. No.: US 2011/0132426 A1
(43) Pub. Date: Jun. 9, 2011

(54) SOLAR CELL MODULE

(76) Inventors: Juwan Kang, Seoul (KR); Jiweon Jeong, Seoul (KR); Jonghwan Kim, Seoul (KR)

(21) Appl. No.: 12/846,632

(22) Filed: Jul. 29, 2010

(30) Foreign Application Priority Data
Dec. 9, 2009 (KR) 10-2009-0121791

(51) Int. Cl. H01L 31/05

(52) U.S. Cl. 136/244

(57) ABSTRACT

A solar cell module includes at least one first solar cell, at least one second solar cell, an upper protective layer positioned on the first solar cell and the second solar cell, a transparent member positioned on the upper protective layer, a lower protective layer positioned under the first solar cell and the second solar cell, and a back sheet positioned under the lower protective layer. The back sheet has at least one conductive pattern for electrically connecting a current collector positioned on a back surface of a first semiconductor substrate of the first solar cell to a current collector positioned on a back surface of a second semiconductor substrate of the second solar cell, and the at least one conductive pattern is straightly formed to connect therebetween.

This application claims priority to and the benefit of Korean Patent Application No. 10-2009-0121791 filed in the Korean Intellectual Property Office on Dec. 9, 2009, the entire contents of which is incorporated herein by reference.

### BACKGROUND OF THE INVENTION

1. Field of the Invention

Embodiments of the invention relate to a solar cell module including a plurality of solar cells.

2. Description of the Related Art

Recently, as existing energy sources such as petroleum and coal are expected to be depleted, interests in alternative energy sources for replacing the existing energy sources are increasing. Among the alternative energy sources, solar cells generating electric energy from solar energy have been particularly spotlighted.

A solar cell generally includes a p-type semiconductor substrate, an n-type emitter layer on one surface, for example, a light receiving surface of the p-type semiconductor substrate, and a first electrode and a second electrode respectively formed on the substrate and the emitter layer. In other words, the first and second electrodes are respectively formed on the different semiconductors. At least one current collector such as a bus bar is formed in each of the first and second electrodes.

When light is incident on the solar cell, electrons inside the semiconductors become free electrons (hereinafter referred to as “electrons”) by the photoelectric effect. Further, electrons and holes respectively move to the n-type semiconductor (e.g., the emitter layer) and the p-type semiconductor (e.g., the substrate) in accordance with the principle of the p-n junction. The holes moving to the substrate and the electrons moving to the emitter layer are respectively collected by the first electrode and the second electrode respectively connected to the substrate and the emitter layer. Then, the holes and the electrons move to the respective current collectors connected to the first and second electrodes.

Because a very small amount of voltage and current are generated from one solar cell having the above-described structure, a solar cell module fabricated by connecting a plurality of solar cells each having the above-described structure in series or in parallel to one another is used to obtain a desired amount of output. The solar cell module is a moisture-proof module fabricated in a panel form.

In the solar cell module, the electrons and the holes collected by the current collectors of each solar cell are collected by a junction box formed on a back surface of the solar cell module, and an interconnector, for example, a ribbon is used to connect the solar cells to one another.

In the related art solar cell module, all of the solar cells each include the semiconductor substrate of the same conductive type. Thus, when the adjacent solar cells are electrically connected to one another using the interconnector, one terminal of the interconnector is connected to the first electrode positioned on a light receiving surface of one solar cell, and the other terminal of the interconnector is connected to the second electrode positioned on a surface opposite a light receiving surface of another solar cell adjacent to the one solar cell.

Because of these reasons, manual work is required to electrically connect the related art solar cells to one another using the interconnector. Accordingly, yield in a module process of the related art solar cell module is reduced, and work time increases.

Further, in the related art solar cell module, because a portion of the interconnector for electrically connecting the two adjacent solar cells to each other is positioned in a space between the two adjacent solar cells, the space for the interconnector has to be secured between the solar cells. A magnitude of the space, i.e., a distance between the solar cells is constant, for example, about 3 mm or more. Accordingly, there is a limit to a reduction in the size of the solar cell module.

Further, because an electrical connection between the solar cells is achieved by only the interconnector, it is difficult to form a bypass diode inside the related art solar cell module. Thus, the bypass diode is generally formed inside the junction box of the related art solar cell module. However, in this case, power reduction is generated because of local shadowing.

### SUMMARY OF THE INVENTION

In one aspect, there is a solar cell module including at least one first solar cell, a first electron current collector, and a first hole current collector, at least one of the first electron current collector and the first hole current collector being positioned on a back surface of the first semiconductor substrate, at least one second solar cell, a second hole current collector, and a second electron current collector, at least one of the second hole current collector and the second electron current collector being positioned on a back surface of the second semiconductor substrate, an upper protective layer positioned on the at least one first solar cell and the at least one second solar cell, a transparent member positioned on the upper protective layer, a lower protective layer positioned under the at least one first solar cell and the at least one second solar cell, and a back sheet positioned under the lower protective layer, wherein the back sheet has at least one conductive pattern for electrically connecting the at least one of the first electron current collector and the first hole current collector on the back surface of the first semiconductor substrate to the at least one of the second hole current collector and the second electron current collector on the back surface of the second semiconductor substrate, and the at least one conductive pattern is straightly formed to connect therebetween.

### BRIEF DESCRIPTION OF THE DRAWINGS

The accompanying drawings, which are included to provide a further understanding of the invention and are incorporated in and constitute a part of this specification, illustrate embodiments of the invention and together with the description serve to explain the principles of the invention. In the drawings:

FIG. 1 is an exploded perspective view of a solar cell module according to an embodiment of the invention;

FIG. 2 is a cross-sectional view taken along a direction X-X′ of FIG. 1;

FIG. 3 is a cross-sectional view taken along a direction Y-Y′ of FIG. 1;

FIG. 4 is a partial perspective view of a first solar cell according to an embodiment of the invention;

FIG. 5 is a partial perspective view of a second solar cell according to an embodiment of the invention;

FIG. 6 is a plane view of a back sheet according to an embodiment of the invention;

FIG. 7 is a perspective view of a solar cell module according to another embodiment of the invention;

FIG. 8 is a partial perspective view of a first solar cell according to another embodiment of the invention;

FIG. 9 is a partial perspective view of a second solar cell according to another embodiment of the invention; and

FIG. 10 is a plane view of a back sheet according to another embodiment of the invention.

### DETAILED DESCRIPTION OF THE EMBODIMENTS

The invention will be described more fully hereinafter with reference to the accompanying drawings, in which example embodiments of the inventions are shown. This invention may, however, be embodied in many different forms and should not be construed as limited to the embodiments set forth herein.

In the drawings, the thickness of layers, films, panels, regions, etc., are exaggerated for clarity. Like reference numerals designate like elements throughout the specification. It will be understood that when an element such as a layer, film, region, or substrate is referred to as being “on” another element, it can be directly on the other element or intervening elements may also be present. In contrast, when an element is referred to as being “directly on” another element, there are no intervening elements present. Further, it will be understood that when an element such as a layer, film, region, or substrate is referred to as being “entirely” on another element, it may be on the entire surface of the other element and may not be on a portion of an edge of the other element.

Reference will now be made in detail to embodiments of the invention, examples of which are illustrated in the accompanying drawings.

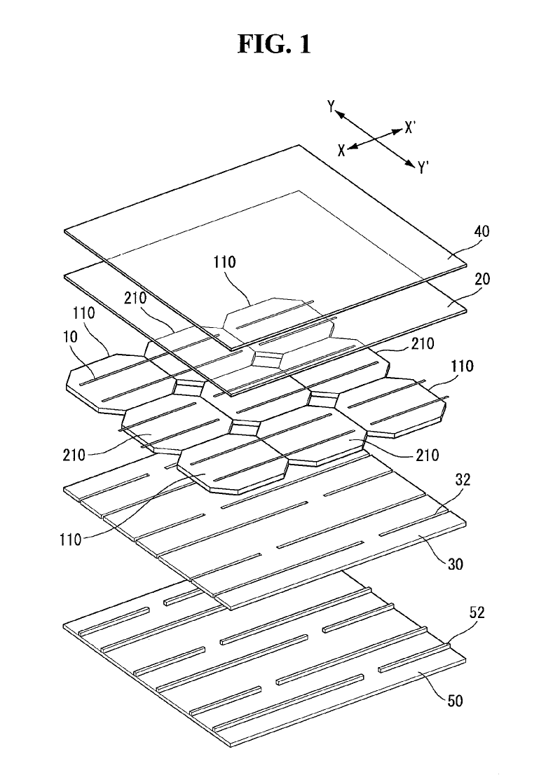

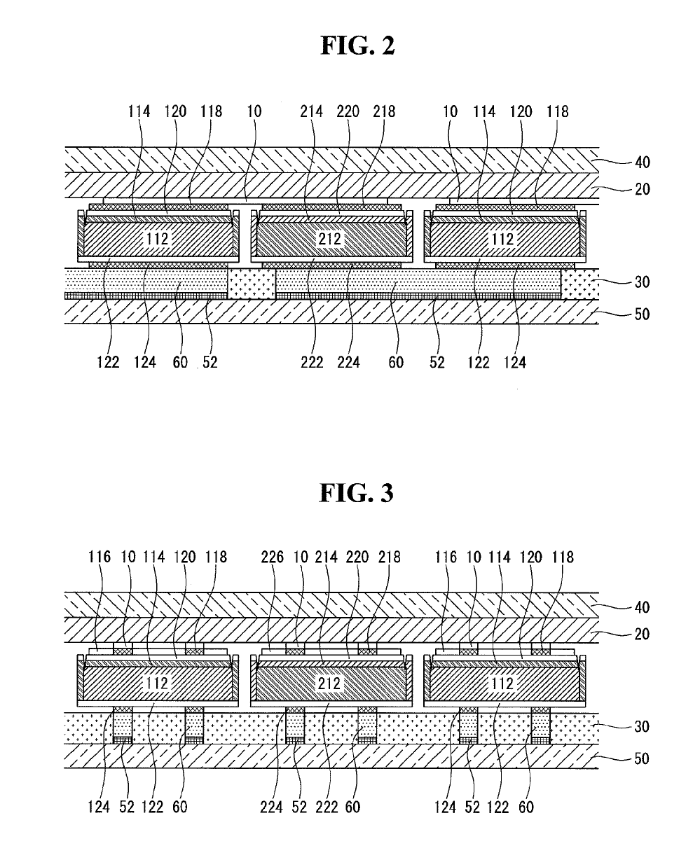

FIG. 1 is an exploded perspective view of a solar cell module according to an embodiment of the invention. FIGS. 2 and 3 are cross-sectional views illustrating an arrangement structure and an electrical connection structure of a plurality of solar cells before a lamination process is performed. More specifically, FIG. 2 is a cross-sectional view taken along a direction X-X′ of FIG. 1, and FIG. 3 is a cross-sectional view taken along a direction Y-Y′ of FIG. 1.

As shown in FIGS. 1 to 3, a solar cell module according to an embodiment of the invention includes a plurality of solar cells 110 and 210, an interconnector 10 and a plurality of conductive patterns 52 for electrically connecting the plurality of solar cells 110 and 210 to one another, upper and lower protective layers 20 and 30 for protecting the solar cells 110 and 210, a transparent member 40 on the upper protective layer 20 that is positioned near to light receiving surfaces of the solar cells 110 and 210, a back sheet 50 underlying the lower protective layer 30 that is positioned near to surfaces opposite the light receiving surfaces of the solar cells 110 and 210, and a frame receiving the components 110, 210, 10, 52, 20, 30, 40, and 50 that form an integral body through a lamination process.

The back sheet 50 prevents moisture or oxygen from penetrating into a back surface of the solar cell module, thereby protecting the solar cells 110 and 210 from an external environment. The back sheet 50 may have a multi-layered structure including a moisture/oxygen penetrating prevention layer, a chemical corrosion prevention layer, a layer having insulating characteristics, etc.

The upper and lower protective layers 20 and 30 and the solar cells 110 and 210 form an integral body when a lamination process is performed in a state where the upper and lower protective layers 20 and 30 are respectively positioned on and under the solar cells 110 and 210. The upper and lower protective layers 20 and 30 prevent corrosion of metal resulting from the moisture penetration and protect the solar cells 110 and 210 from an impact. The upper and lower protective layers 20 and 30 may be formed of ethylene vinyl acetate (EVA), polyvinyl butyral (PVB), partial oxide of ethylene vinyl acetate (EVA), silicon resin, ester-based resin, and olefin-based resin. Other materials may be used.

The transparent member 40 on the upper protective layer 20 is formed of a tempered glass having a high light transmittance and excellent damage prevention characteristic. The tempered glass may be a low iron tempered glass containing a small amount of iron. The transparent member 40 may have an embossed inner surface so as to increase a scattering effect of light.

A method of manufacturing the solar cell module sequentially includes testing the solar cells 110 and 210, electrically connecting the tested solar cells 110 and 210 to one another using the interconnector 10 and the conductive patterns 52, sequentially disposing the components 110, 210, 20, 30, 40, and 50, for example, sequentially disposing the back sheet 50, the lower protective layer 30, the solar cells 110 and 210, the upper protective layer 20, and the transparent member 40 from the bottom of the solar cell module in the order named, performing the lamination process in a vacuum state to form an integral body of the components 110, 210, 20, 30, 40, and 50, performing an edge trimming process, testing the solar cell module, and the like.

In the embodiment of the invention, the plurality of solar cells 110 and 210 disposed between the upper protective layer 20 and the lower protective layer 30 include at least one first solar cell 110 and at least one second solar cell 210.

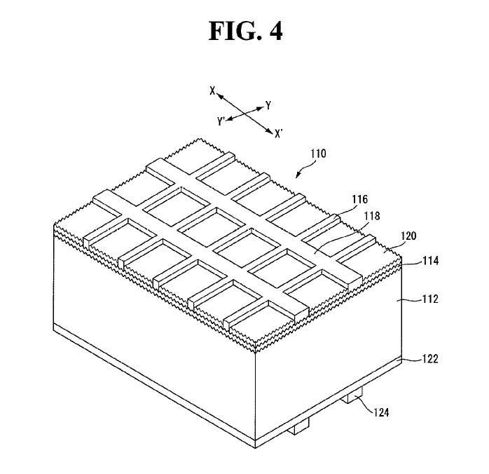

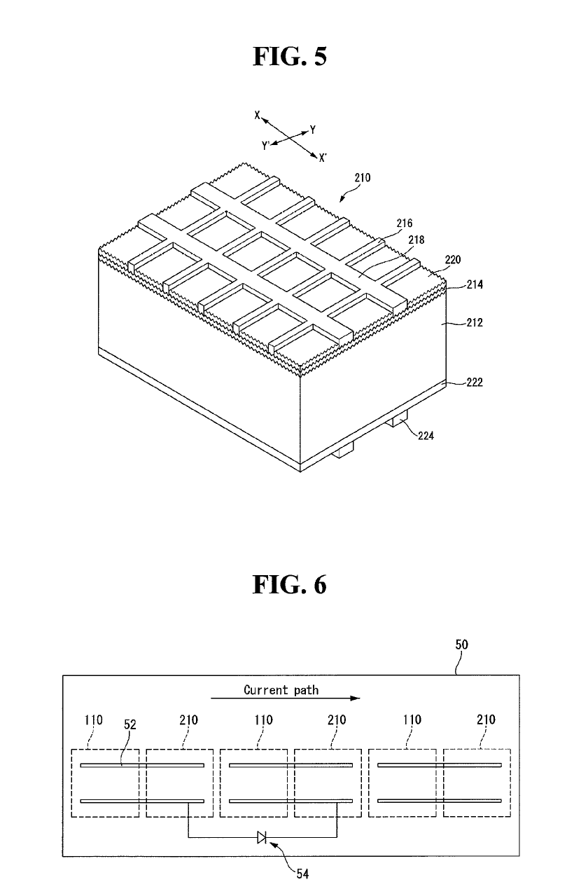

The first and second solar cells according to the embodiment of the invention are described below with reference to FIGS. 4 and 5. FIG. 4 is a partial perspective view of the first solar cell 110, and FIG. 5 is a partial perspective view of the second solar cell 210.

As shown in FIG. 4, the first solar cell 110 includes a first semiconductor substrate 112 formed of first conductive type silicon, for example, p-type silicon, though not required. Silicon used in the first semiconductor substrate 112 may be single crystal silicon, polycrystalline silicon, or amorphous silicon. When the first semiconductor substrate 112 is of a p-type, the first semiconductor substrate 112 contains impurities of a group III element such as boron (B), gallium (Ga), and indium (In).

The surface of the first semiconductor substrate 112 may be textured to form a textured surface corresponding to an uneven surface or having uneven characteristics.

When the surface of the first semiconductor substrate 112 is the textured surface, a light reflectance in a light receiving surface of the first semiconductor substrate 112 is reduced. Further, because both a light incident operation and a light reflection operation are performed on the textured surface of the first semiconductor substrate 112, light is confined in the first solar cell 110. Hence, a light absorption increases, and efficiency of the first solar cell 110 is improved. In addition, because a reflection loss of light incident on the first semiconductor substrate 112 decreases, an amount of light incident on the first semiconductor substrate 112 further increases.

An emitter layer 114 is positioned in the light receiving surface of the first semiconductor substrate 112. The emitter layer 114 is an impurity region doped with impurities of a second conductive type (for example, an n-type) opposite the first conductive type of the first semiconductor substrate 112. The emitter layer 114 forms a p-n junction along with the first semiconductor substrate 112. When the emitter layer 114 is of the n-type, the emitter layer 114 may be formed by doping the first semiconductor substrate 112 with impurities of a group V element such as phosphor (P), arsenic (As), and antimony (Sb).

When energy produced by light incident on the first semiconductor substrate 112 is applied to carriers inside the semiconductors, electrons move to the n-type semiconductor and holes move to the p-type semiconductor. Thus, when the first semiconductor substrate 112 is of the p-type and the emitter layer 114 is of the n-type, the holes move to the p-type substrate 112 and the electrons move to the n-type emitter layer 114.

A plurality of first electron electrodes 116 are positioned on the emitter layer 114 to be spaced apart from one another. The first electron electrodes 116 are electrically connected to the emitter layer 114 and extend in one direction. Each of the first electron electrodes 116 collects carriers (e.g., electrons) moving to the emitter layer 114. The first electron electrodes 116 are formed of at least one conductive material. The conductive material may be at least one selected from the group consisting of nickel (Ni), copper (Cu), silver (Ag), aluminum (Al), tin (Sn), zinc (Zn), indium (In), titanium (Ti), gold (Au), and a combination thereof. Other conductive materials may be used for the first electron electrodes 116.

At least one first electron current collector 118 is positioned on the emitter layer 114. The first electron current collector 118 referred to as a bus bar is formed in a direction crossing the first electron electrodes 116. Thus, the first electron electrodes 116 and the first electron current collector 118 are positioned on the emitter layer 114 in a crossing structure. The first electron current collector 118 is electrically connected to the emitter layer 114 and the first electron electrodes 116. Thus, the first electron current collector 118 outputs the carriers (e.g., electrons) transferred from the first electron electrodes 116 to an external device. The first electron current collector 118 is formed of at least one conductive material. The conductive material may be at least one selected from the group consisting of Ni, Cu, Ag, Al, Sn, Zn, In, Ti, Au, and a combination thereof. Other conductive materials may be used for the first electron current collector 118.

In the embodiment of the invention, the first electron current collector 118 may contain the same material as or a different material from the first electron electrodes 116.

The first electron electrodes 116 and the first electron current collector 118 may be electrically connected to the emitter layer 114 in a process in which the conductive material is coated on an anti-reflection layer 120, is patterned in a pattern form shown in FIG. 2, and is fired.

The anti-reflection layer 120 is formed on the emitter layer 114 on which the first electron electrodes 116 and the first electron current collector 118 are not formed. The anti-reflection layer 120 is formed of silicon nitride (SiNx) and/or silicon dioxide (SiO₂). Other materials may be used. The anti-reflection layer 120 reduces a reflectance of light incident on the first solar cell 110 and increases a selectivity of a predetermined wavelength band, thereby increasing the efficiency of the first solar cell 110. The anti-reflection layer 120 may have a thickness of about 70 nm to 80 nm. The anti-reflection layer 120 may be omitted, if desired.

A first hole electrode 122 is positioned on a surface (i.e., a back surface of the first semiconductor substrate 112) opposite the light receiving surface of the first semiconductor substrate 112. The first hole electrode 122 collects carriers (e.g., holes) moving to the first semiconductor substrate 112. The first hole electrode 122 is formed of at least one conductive material. The conductive material may be at least one selected from the group consisting of Ni, Cu, Ag, Al, Sn, Zn, In, Ti, Au, and a combination thereof Other conductive materials may be used for the first hole electrode 122.

A first hole current collector 124 is positioned under the first hole electrode 122. The first hole current collector 124 is formed in a direction crossing the first electron electrodes 116, i.e., in a direction parallel to the first electron current collector 118. The first hole current collector 124 is electrically connected to the first hole electrode 122. Thus, the first hole current collector 124 outputs the carriers (e.g., holes) transferred from the first hole electrode 122 to the external device. The first hole current collector 124 is formed of at least one conductive material. The conductive material may be at least one selected from the group consisting of Ni, Cu, Ag, Al, Sn, Zn, In, Ti, Au, and a combination thereof. Other conductive materials may be used for the first hole current collector 124.

The first solar cell 110 may further include a back surface field (BSF) layer between the first hole electrode 122 and the first semiconductor substrate 112. The back surface field layer is a region (e.g., a p⁺-type region) that is more heavily doped with impurities of the same conductive type as the first semiconductor substrate 112 than the first semiconductor substrate 112. The back surface field layer serves as a potential barrier of the first semiconductor substrate 112. Thus, because a recombination and/or a disappearance of electrons and holes around the back surface of the first semiconductor substrate 112 are prevented or reduced, the efficiency of the first solar cell 110 is improved.

So far, the configuration of the first solar cell 110 is described in detail. Configuration of the second solar cell 210 is substantially the same as the first solar cell 110, except that conductive types of the corresponding components of the first and second solar cells 110 and 210 are opposite to each other. Thus, the configuration of the second solar cell 210 may be briefly described with reference to FIG. 5.

As shown in FIG. 5, a second semiconductor substrate 212 of the second solar cell 210 is formed of second conductive type silicon, for example, n-type silicon, though not required. When the second semiconductor substrate 212 is of the n-type, the second semiconductor substrate 212 may contain impurities of a group V element such as phosphor (P), arsenic (As), and antimony (Sb).

Because an emitter layer 214 forms a p-n junction along with the second semiconductor substrate 212, the emitter layer 214 is of the first conductive type (e.g., a p-type). Thus, when the emitter layer 214 is of the p-type, the emitter layer 214 may be formed by doping the second semiconductor substrate 212 with impurities of a group III element such as boron (B), gallium (Ga), and indium (In).

In the second solar cell 210 having the above-described structure, electrons move to the second semiconductor substrate 212, and holes move to the emitter layer 214.

A plurality of second hole electrodes 216 and at least one second hole current collector 218 are positioned on the emitter layer 214, and a second electron electrode 222 and a second electron current collector 224 are positioned on a back surface of the second semiconductor substrate 212.

The second solar cell 210 includes an anti-reflection layer 220. The second solar cell 210 may have a textured surface of the second semiconductor substrate 212 in the same manner as the first solar cell 110 and may further include a back surface field layer.

The second hole electrodes 216, the second hole current collector 218, the second electron electrode 222, and the second electron current collector 224 may be formed of at least one conductive material selected from the group consisting of Ni, Cu, Ag, Al, Sn, Zn, In, Ti, Au, and a combination thereof. Other conductive materials may be used.

FIGS. 4 and 5 illustrate that the first hole current collector 124 is positioned on the first hole electrode 122 and the second electron current collector 224 is positioned on the second electron electrode 222. However, the first hole electrode 122 and the first hole current collector 124 may be formed on the same plane (or the same plane level or may be coplanar), and the second electron electrode 222 and the second electron current collector 224 may be formed on the same plane (or the same plane level or may be coplanar).

In other words, the first hole current collector 124 may be positioned on the back surface of the first semiconductor substrate 112 on which the first hole electrode 122 is not formed, and the second electron current collector 224 may be positioned on the back surface of the second semiconductor substrate 212 on which the second electron electrode 222 is not formed. In this case, the first hole electrode 122 and the first hole current collector 124 are formed in the same direction, and the second electron electrode 222 and the second electron current collector 224 are formed in the same direction.

Referring again to FIGS. 1 to 3, the first solar cells 110 and the second solar cells 210 are arranged in a matrix structure. Although FIG. 1 illustrates that the solar cells 110 and 210 on the lower protective layer 30 have a structure of 3×3 matrix, the number of solar cells 110 and 210 in row and/or column directions may vary, if necessary.

In the embodiment of the invention, at least one first solar cell 110 and at least one second solar cell 210 are arranged adjacently to each other. Preferably, the first solar cells 110 and the second solar cells 210 may be alternately arranged.

Further, the first solar cell 110 is configured so that the first electron electrodes 116 and the first electron current collector 118 are positioned toward a light source, and the second solar cell 210 is configured so that the second hole electrodes 216 and the second hole current collector 218 are positioned toward the light source. Accordingly, the first electron current collector 118 of the first solar cell 110 and the second hole current collector 218 of the second solar cell 210 are positioned on the same plane (or the same plane level), and the first hole current collector 124 of the first solar cell 110 and the second electron current collector 224 of the second solar cell 210 are positioned on the same plane (or the same plane level).

When the first solar cells 110 and the second solar cells 210 are arranged in the matrix structure, each first solar cell 110 and each second solar cell 210 are arranged so that a longitudinal direction X-X′ of the first electron current collector 118 is equal to a longitudinal direction X-X′ of the second hole current collector 218, and at the same time, a longitudinal direction X-X′ of the first hole current collector 124 is equal to a longitudinal direction X-X′ of the second electron current collector 224. Hence, one end of the first electron current collector 118 is opposite to one end of the second hole current collector 218, and one end of the first hole current collector 124 is opposite to one end of the second electron current collector 224.

Accordingly, in the solar cell module having the above-described matrix structure, the interconnector 10 for electrically connecting the first electron current collector 118 of the first solar cell 110 to the second hole current collector 218 of the second solar cell 210 may be straightly positioned on the same plane (or the same plane level). In this arrangement, the first electron current collector 118, the second hole current collector 218, and the interconnector 10 are position in a straight line or are collinear.

The interconnector 10 may have a textured surface in the same manner as the first and second semiconductor substrates 112 and 212. In this case, the textured surface of the interconnector 10 may be a surface opposite a surface of the interconnector 10 contacting the light receiving surfaces of the first and second semiconductor substrates 112 and 212. The interconnector 10 having the above-described configuration can efficiently increase an absorptance of light while preventing a reduction in an adhesive strength between the interconnector 10 and the corresponding current collectors of the solar cells 110 and 210.

The lower protective layer 30 underlying the solar cells 110 and 210 has a plurality of openings 32. The openings 32 are positioned at locations corresponding to the first hole current collector 124 and the second electron current collector 224 respectively positioned on the back surfaces of the substrates 112 and 212 of the solar cells 110 and 210. At least a portion of each of the current collectors 124 and 224 is exposed through the openings 32. A width of each of the openings 32 is equal to or less than or greater than a width of each of the current collectors 124 and 224.

The plurality of conductive patterns 52 are positioned on the back sheet 50. In the embodiment of the invention, the conductive patterns 52 are formed of Cu. However, the conductive patterns 52 may be formed of a conductive material such as Ag.

The conductive patterns 52 are formed in the straight form (or parallel) on the back sheet 50, so that the first hole current collector 124 and the second electron current collector 224 of the solar cells 110 and 210 straightly positioned (in a straight line or collinear) on the same plane (or the same plane level) are electrically connected to each other. Hence, the portions of the current collectors 124 and 224 exposed through the openings 32 of the lower protective layer 30 are opposite to the conductive patterns 52. It is preferable that the size, more particularly the width of each opening 32 is greater than a width of each conductive pattern 52. When the width of each opening 32 is greater than a width of each conductive pattern 52, an electrical connection between the conductive patterns 52 and the corresponding current collectors can be well performed even if misalignment between the openings 32 and the conductive patterns 52 occurs.

As shown in FIG. 1, the conductive patterns 52 are parallel, but immediately adjacent conductive patterns 52 are not aligned with each other. That is, ends of the adjacent conductive patterns 52 that are side-by-side are not aligned, but instead, are offset from each other. Additionally, in an embodiment of the invention, the plurality of openings 32 of the lower protective layer 30 are arranged in a corresponding manner as the plurality of conductive patterns 52.

Conductive adhesives 60 are respectively positioned on the conductive patterns 52 and contact the exposed portions of the corresponding current collectors 124 and 224 through the openings 32 of the lower protective layer 30. Hence, the conductive patterns 52 on the back sheet 50 are electrically connected to the first hole current collector 124 of each first solar cell 110, and at the same time, are electrically connected to the second electron current collector 224 of each second solar cell 210.

Although it is not shown, an insulating sheet formed of an insulating material may be further positioned between the lower protective layer 30 and the back sheet 50.

In the solar cell module according to the embodiment of the invention, the first electron current collector 118 of the first solar cell 110 and the second hole current collector 218 of the second solar cell 210 are positioned on the same plane (or the same plane level), and the first hole current collector 124 of the first solar cell 110 and the second electron current collector 224 of the second solar cell 210 are positioned on the same plane (or the same plane level). Accordingly, the first electron current collector 118 and the second hole current collector 218 positioned on the light receiving surface of the solar cells 110 and 210 can be electrically connected to each other using the interconnector 10. The first hole current collector 124 and the second electron current collector 224 can be electrically connected to each other using the conductive patterns 52 and the interconnector 10.

In the solar cell module according to the embodiment of the invention, because the electrical connection between the solar cells can be very easily performed, the yield in the module process of the solar cells can be improved and a distance between the solar cells 110 and 210 can be reduced to be equal to or less than about 1 mm.

As shown in FIG. 6, a bypass diode 54 may be locally and directly formed in the back sheet 50. A bypass forming method using the bypass diode 54 is not limited to a method illustrated in FIG. 6, and other methods may be used. Further, the number of bypasses is not limited.

As above, when the bypass diode 54 is directly formed in the back sheet 50, power reduction resulting from the local shadowing can be efficiently prevented or reduced.

Although the first solar cells 110 and the second solar cells 210 are alternately arranged in the embodiment of the invention described above by way of example, other arrangements may be used. For example, first groups each including the two or three first solar cells 110 and second groups each including the two or three second solar cells 210 may be alternately arranged.

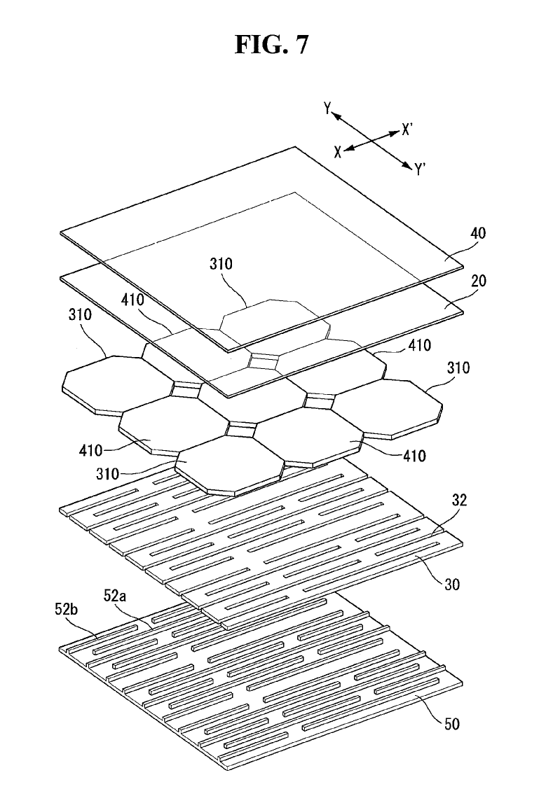

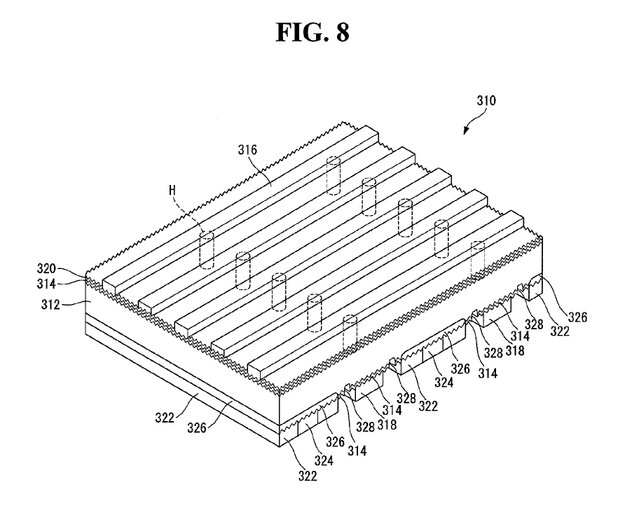

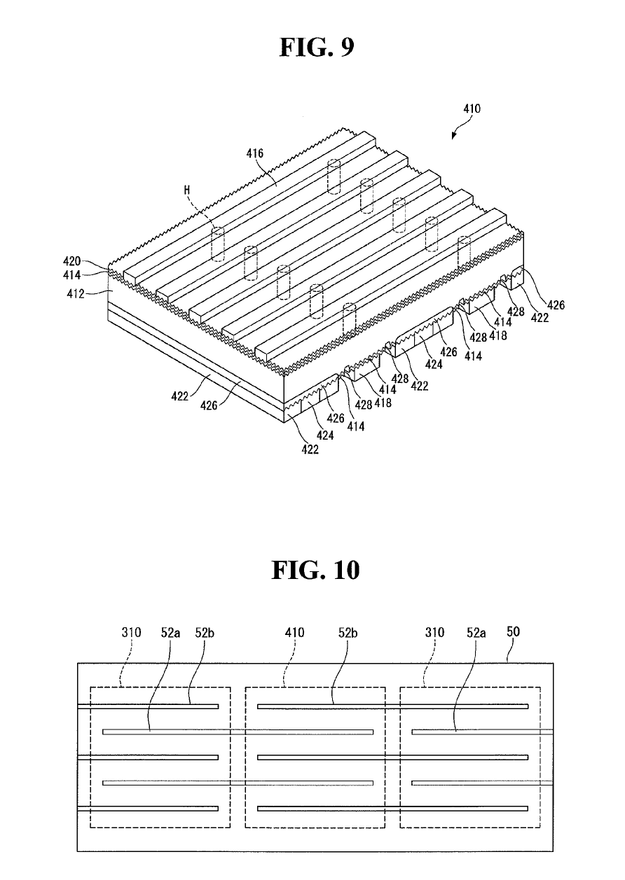

FIG. 7 is a perspective view of a solar cell module according to another embodiment of the invention. FIG. 8 is a perspective view illustrating a schematic configuration of a first solar cell according to another embodiment of the invention. FIG. 9 is a perspective view illustrating a schematic configuration of a second solar cell according to another embodiment of the invention. FIG. 10 is a plane view of a back sheet according to another embodiment of the invention.

As shown in FIG. 7, a solar cell module according to another embodiment of the invention includes a plurality of solar cells 310 and 410, a plurality of conductive patterns 52a and 52b for electrically connecting the plurality of solar cells 310 and 410 to one another, upper and lower protective layers 20 and 30 for protecting the solar cells 310 and 410, a transparent member 40 on the upper protective layer 20 that is positioned near to light receiving surfaces of the solar cells 310 and 410, a back sheet 50 underlying the lower protective layer 30 that is positioned near to surfaces opposite the light receiving surfaces of the solar cells 310 and 410, and a frame receiving the components 310, 410, 52a, 52b, 30, 40, and 50 that form an integral body through a lamination process.

In the embodiment of the invention, the plurality of solar cells 310 and 410 disposed between the upper protective layer 20 and the lower protective layer 30 include at least one first solar cell 310 and at least one second solar cell 410.

The first and second solar cells according to anther embodiment of the invention are described below with reference to FIGS. 8 and 9.

As shown in FIG. 8, the first solar cell 310 includes a first semiconductor substrate 312 of a first conductive type (for example, a p-type) having a plurality of via holes H, an emitter layer 314 positioned in an entire surface of the first semiconductor substrate 312, a plurality of first electron electrodes 316 positioned on the emitter layer 314 of a front surface corresponding to a light receiving surface of the first semiconductor substrate 312, a plurality of first electron current collectors 318 that are positioned on the emitter layer 314 of a back surface opposite the front surface of the first semiconductor substrate 312 in and around the via holes H and are electrically connected to the plurality of first electron electrodes 316, an anti-reflection layer 320 positioned on the emitter layer 314 of the front surface of the first semiconductor substrate 312 on which the first electron electrodes 316 are not positioned, a plurality of first hole electrodes 322 positioned on the back surface of the first semiconductor substrate 312, a plurality of first hole current collectors 324 that are positioned on the back surface of the first semiconductor substrate 312 and are electrically connected to the first hole electrodes 322, and a plurality of back surface field layers 326 positioned between the first hole electrodes 322 and the first semiconductor substrate 312.

When the first semiconductor substrate 312 is of the p-type, the emitter layer 314 may contain second conductive type impurities (for example, n-type impurities).

The first electron electrodes 316 are electrically and physically connected to the emitter layer 314. The first electron electrodes 316 collect carriers (e.g., electrons) moving to the emitter layer 314 and transfer the carriers to the first electron current collectors 318 electrically connected to the first electron electrodes 316 through the via holes H.

The first electron current collectors 318 on the back surface of the first semiconductor substrate 312 extend substantially parallel to one another in a direction crossing the first electron electrodes 316 positioned on the front surface of the first semiconductor substrate 312.

The via holes H in the first semiconductor substrate 312 are formed at crossings of the first electron electrodes 316 and the first electron current collectors 318. At least one of each first electron electrode 316 and each first electron current collector 318 extends to at least one of the front surface and the back surface of the first semiconductor substrate 312 through the via holes H. Thus, the first electron electrodes 316 and the first electron current collectors 318 respectively positioned on opposite surfaces of the first semiconductor substrate 312 are electrically connected to one another.

The first electron current collectors 318 output the carriers (e.g., electrons) transferred from the first electron electrodes 316 to an external device.

The first hole electrodes 322 on the back surface of the first semiconductor substrate 312 are positioned to be spaced apart from the first electron current collectors 318 adjacent to the first hole electrodes 322.

The first hole electrodes 322 are positioned on almost the entire back surface of the first semiconductor substrate 312 excluding a formation area of the first electron current collectors 318 from the back surface of the first semiconductor substrate 312. The first hole electrodes 322 collect carriers (e.g., holes) moving to the first semiconductor substrate 312.

The emitter layer 314 in the back surface of the first semiconductor substrate 312 has a plurality of exposing portions 328 that expose a portion of the back surface of the first semiconductor substrate 312 and surround the first electron current collectors 318. Thus, because the electrical connection between the first electron current collectors 318 for electron collection and the first hole electrodes 322 for hole collection is blocked by the exposing portions 328, the electrons and the holes move smoothly.

The first hole current collectors 324 are positioned on the back surface of the first semiconductor substrate 312 and are electrically and physically connected to the first hole electrodes 322. Further, the first hole current collectors 324 extend substantially parallel to the first electron current collectors 318. Thus, the first hole current collectors 324 collect carriers (e.g., holes) transferred from the first hole electrodes 322 and output the carriers to the external device.

Each of the back surface field layers 326 between the first hole electrodes 322 and the first semiconductor substrate 312 is a region (e.g., a p⁺-type region) that is more heavily doped with impurities of the same conductive type as the first semiconductor substrate 312 than the first semiconductor substrate 312.

So far, the configuration of the first solar cell 310 is described in detail with reference to FIG. 8. Configuration of a second solar cell 410 is substantially the same as the first solar cell 310, except that conductive types of the corresponding components of the first and second solar cells 310 and 410 are opposite to each other. Thus, the configuration of the second solar cell 410 may be briefly described with reference to FIG. 9.

A second semiconductor substrate 412 of the second solar cell 410 is of a second conductive type (for example, an n-type) and has a plurality of via holes H.

Because an emitter layer 414 forms a p-n junction along with the second semiconductor substrate 412, the emitter layer 414 is of a first conductive type (e.g., a p-type). Thus, when the emitter layer 414 is of the p-type, the emitter layer 414 may be formed by doping the second semiconductor substrate 412 with impurities of a group III element such as boron (B), gallium (Ga), and indium (In).

In the second solar cell 410 having the above-described structure, electrons move to the second semiconductor substrate 412, and holes move to the emitter layer 414.

An anti-reflection layer 420 and a plurality of second hole electrodes 416 are positioned on the emitter layer 414. A plurality of second hole current collectors 418 electrically connected to the second hole electrodes 416 through the via holes H, a plurality of second electron electrodes 422, and a plurality of second electron current collectors 424 electrically connected to the second electron electrodes 422 are positioned on a surface (i.e., a back surface) opposite a light receiving surface of the second semiconductor substrate 412.

The second solar cell 410 may have a textured surface of the second semiconductor substrate 412 in the same manner as the first solar cell 310. The second solar cell 410 further includes a plurality of back surface field layer 426 and a plurality of expositing portions 428.

An arrangement structure and an electrical connection structure of the first and second solar cells 310 and 410 are described below with reference to FIGS. 7 to 10.

At least one first solar cell 310 and at least one second solar cell 410 are arranged adjacently to each other in a matrix structure in the same manner as the solar cells 110 and 210. Preferably, the first solar cells 310 and the second solar cells 410 may be alternately arranged.

Further, the first solar cell 310 is configured so that the first electron electrodes 316 are positioned toward a light source, and the second solar cell 410 is configured so that the second hole electrodes 416 are positioned toward the light source. Accordingly, the first electron current collectors 318, the first hole electrodes 322, and the first hole current collectors 324 of the first solar cell 310 and the second hole current collectors 418, the second electron electrodes 422, and the second electron current collectors 424 of the second solar cell 410 are positioned on the same plane (or the same plane level).

When the first solar cells 310 and the second solar cells 410 are arranged in the matrix structure, the first solar cells 310 and the second solar cells 410 are arranged so that a longitudinal direction of the first electron current collectors 318 is equal to a longitudinal direction of the second hole current collectors 418, and at the same time, a longitudinal direction of the first hole current collectors 324 is equal to a longitudinal direction of the second electron current collectors 424. Hence, one end of each first electron current collector 318 is opposite to one end of each second hole current collector 418, and one end of each first hole current collector 324 is opposite to one end of each second electron current collector 424.

The conductive patterns 52a for electrically connecting the first electron current collectors 318 to the second hole current collectors 418 and the conductive patterns 52b for electrically connecting the first hole current collectors 324 to the second electron current collectors 424 are formed on the back sheet 50.

A plurality of openings 32 are formed in the lower protective layer 30 at locations corresponding to the conductive patterns 52a and 52b. At least a portion of the corresponding current collector is exposed through each of the openings 32. It is preferable that a width of each of the openings 32 is greater than a width of each of the conductive patterns 52a and 52b. As above, when the width of each of the openings 32 is greater than the width of each of the conductive patterns 52a and 52b, an electrical connection between the conductive patterns 52a and 52b and the corresponding current collectors can be well performed even if misalignment between the openings 32 and the conductive patterns 52a and 52b occurs. Further, the electrical connection between the conductive patterns 52a and 52b and the corresponding current collectors may be performed using a conductive adhesive in the same manner as the above-described embodiment.

Accordingly, in the solar cell module having the above-described matrix stricture, the first electron current collectors 318 of the first solar cell 310 and the second hole current collectors 418 of the second solar cell 410 are straightly connected to one another in the same plane (or the same plane level) using the conductive patterns 52a and the conductive adhesive filled in the openings 32. Further, the first hole current collectors 324 of the first solar cell 310 and the second electron current collectors 424 of the second solar cell 410 are straightly connected to one another in the same plane (or the same plane level) using the conductive patterns 52b and the conductive adhesive filled in the openings 32.

In other words, in the solar cell module according to the embodiment of the invention, because the first electron current collectors 318 of the first solar cell 310 and the second hole current collectors 418 of the second solar cell 410 are straightly positioned (in a straight line or collinear) on the same plane (or the same plane level) and the first hole current collectors 324 of the first solar cell 310 and the second electron current collectors 424 of the second solar cell 410 are straightly positioned (in a straight line or collinear) on the same plane (or the same plane level), the electrical connection between the solar cells 310 and 410 using the conductive patterns 52a and 52b may be easily performed. In this arrangement, the first electron current collector 318, the second hole current collector 418, and the conductive pattern 52a are position in a straight line or are collinear. Also, first hole current collectors 324, the second electron current collectors 424, and the conductive patterns 52b are position in a straight line or are collinear. Accordingly, a yield in a module process of the solar cells 310 and 410 can be improved, and a distance between the solar cells 310 and 410 can be reduced to be equal to or less than about 1 mm.

As shown in FIG. 7, a first plurality of conductive patterns 52a and a second plurality of conductive patterns 52b are parallel, but immediately adjacent conductive patterns 52a and conductive patterns 52b are not aligned or misaligned with each other. That is, ends of the adjacent conductive patterns 52a and 52b that are side-by-side are not aligned, but instead, are offset from each other. Additionally, in an embodiment of the invention, the plurality of openings 32 of the lower protective layer 30 are arranged in a corresponding manner as the plurality of conductive patterns 52a and 52b. Nevertheless, the first plurality of the conductive patterns 52a are aligned with each other, and the second plurality of the conductive patterns 52b are aligned with each other. In the embodiment shown, the first plurality of the conductive patterns 52a respectively alternate with the second plurality of the conductive patterns 52b.

Additionally, a bypass diode may be formed in the embodiment of the invention.

Although embodiments have been described with reference to a number of illustrative embodiments thereof, it should be understood that numerous other modifications and embodiments can be devised by those skilled in the art that will fall within the scope of the principles of this disclosure. More particularly, various variations and modifications are possible in the component parts and/or arrangements of the subject combination arrangement within the scope of the disclosure, the drawings and the appended claims. In addition to variations and modifications in the component parts and/or arrangements, alternative uses will also be apparent to those skilled in the art.

What is claimed is:

1. A solar cell module, comprising:
at least one first solar cell including a first semiconductor substrate, a first electron current collector, and a first hole current collector, at least one of the first electron current collector and the first hole current collector being positioned on a back surface of the first semiconductor substrate;
at least one second solar cell including a second semiconductor substrate, a second hole current collector, and a second electron current collector, at least one of the second hole current collector and the second electron current collector being positioned on a back surface of the second semiconductor substrate;
an upper protective layer positioned on the at least one first solar cell and the at least one second solar cell;
a transparent member positioned on the upper protective layer;
a lower protective layer positioned under the at least one first solar cell and the at least one second solar cell; and
a back sheet positioned under the lower protective layer,
wherein the back sheet has at least one conductive pattern for electrically connecting the at least one of the first electron current collector and the first hole current collector on the back surface of the first semiconductor substrate to the at least one of the second hole current collector and the second electron current collector on the back surface of the second semiconductor substrate, and the at least one conductive pattern is straightly formed to connect therebetween.

2. The solar cell module of claim 1, wherein the lower protective layer includes a plurality of openings positioned at locations corresponding to the at least one of the first electron current collector and the first hole current collector on the back surface of the first semiconductor substrate, and the at least one of the second hole current collector and the second electron current collector on the back surface of the second semiconductor substrate.

3. The solar cell module of claim 2, wherein the plurality of openings is formed at locations that match the at least one conductive pattern, and widths of the plurality of openings is greater than a width of the at least one conductive pattern.

4. The solar cell module of claim 1, wherein the lower protective layer is disposed between the at least one second solar cell and the at least one first solar cell, and the back sheet.

5. The solar cell module of claim 1, wherein a bypass diode is positioned at the back sheet.

6. The solar cell module of claim 1, wherein the first semiconductor substrate is of a first conductive type, and the second semiconductor substrate is of a second conductive type opposite the first conductive type.

7. The solar cell module of claim 1, wherein the first electron current collector and the first hole current collector of the at least one first solar cell are respectively positioned on a light receiving surface and the back surface of the first semiconductor substrate, and the second hole current collector and the second electron current collector of the at least one second solar cell are respectively positioned on a light receiving surface and the back surface of the second semiconductor substrate.

8. The solar cell module of claim 1, wherein the first electron current collector and the second hole current collector are straightly connected to each other on the same plane level using an interconnector.

9. The solar cell module of claim 8, wherein the first electron current collector, the second hole current collector, and the interconnector are collinear.

10. The solar cell module of claim 8, wherein a conductive adhesive is positioned inside the plurality of openings to electrically connect the first hole current collector and the second electron current collector to the at least one conductive pattern.

11. The solar cell module of claim 1, wherein the first electron current collector and the first hole current collector are positioned on the back surface of the first semiconductor substrate in the same direction, and
the second electron current collector and the second hole current collector are positioned on the back surface of the second semiconductor substrate in the same direction.

12. The solar cell module of claim 11, wherein the first electron current collector and the second hole current collector are positioned in a straight line, and the first hole current collector and the second electron current collector are positioned in a straight line.

13. The solar cell module of claim 12, wherein the first electron current collector and the second hole current collector are electrically connected to each other using one conductive pattern, and wherein the first hole current collector and the second electron current collector are electrically connected to each other using another conductive pattern.

14. The solar cell module of claim 13, wherein the first conductive type is a p-type, the at least one first solar cell further includes a plurality of first via holes passing through the first semiconductor substrate, an n-type emitter layer positioned in the light receiving surface of the first semiconductor substrate and in the plurality of first via holes, a first electron electrode positioned on the emitter layer in the light receiving surface of the first semiconductor substrate, and a first hole electrode that is positioned on the back surface of the first semiconductor substrate and is electrically connected to the first hole current collector, and
the first electron current collector is electrically connected to the first electron electrode through at least one of the plurality of first via holes.

15. The solar cell module of claim 14, wherein the first electron current collector is formed in a direction crossing the first electron electrode, and the at least one first via hole is formed at a crossing of the first electron current collector and the first electron electrode.

16. The solar cell module of claim 14, wherein the second conductive type is an n-type,
the at least one second solar cell further includes a plurality of second via holes passing through the second semiconductor substrate, a p-type emitter layer positioned in the light receiving surface of the second semiconductor substrate and in the plurality of second via holes, a second hole electrode positioned on the emitter layer in the light receiving surface of the second semiconductor substrate, and a second electron electrode that is positioned on the back surface of the second semiconductor substrate and is electrically connected to the second electron current collector, and
the second hole current collector is electrically connected to the second hole electrode through at least one of the plurality of second via holes.

17. The solar cell module of claim 16, wherein the second hole current collector is formed in a direction crossing the second hole electrode, and the at least one second via hole is formed at a crossing of the second hole current collector and the second hole electrode.

18. The solar cell module of claim 16, wherein a conductive adhesive is positioned inside the plurality of openings to electrically connect the first hole current collector and the second electron current collector to the conductive pattern and to electrically connect the first electron current collector and the second hole current collector to the at least one conductive pattern.

19. The solar cell module of claim 1, wherein the back sheet includes a plurality of conductive patterns that is parallel to each other and at least one of the plurality of conductive patterns is misaligned with at least another of the plurality of conductive patterns.

20. The solar cell module of claim 19, wherein a first plurality of the conductive patterns are aligned with each other, a second plurality of the conductive patterns are aligned with each other, and at least one of the first plurality of the conductive patterns and at least one of the second plurality of the conductive patterns are misaligned with each other so that the first plurality of the conductive patterns respectively alternate with the second plurality of the conductive patterns.
